(19) United States
(12) Patent Application Publication
(10) Pub. No.: US 2024/0429683 A1
(43) Pub. Date: Dec. 26, 2024

(54) SEMICONDUCTOR STRUCTURE FOR OPTOELECTRONIC APPLICATIONS

(71) Applicant: SOITEC, BERNIN (FR)

(72) Inventors: Christophe Figuet, Grenoble (FR); Isabelle Huyet, Crolles (FR)

(21) Appl. No.: 18/685,257

(22) PCT Filed: Sep. 8, 2022
(86) PCT No.: PCT/FR2022/051695

§ 371 Date: Feb. 21, 2024

(30) Foreign Application Priority Data
Sep. 22, 2021 (FR) FR2109949

(51) Int. Cl. H01S 5/183

(52) U.S. Cl. CPC H01S 5/18377

(57) ABSTRACT

A semiconductor structure for optoelectronic applications; comprises a first layer made of a crystalline semiconductor, the layer being disposed on an intermediate layer including or adjacent to a direct-bonding interface, the intermediate layer being disposed on a second layer made of a crystalline semiconductor material. The intermediate layer is composed of a material that is different from those of the first and second layers, and the attenuation coefficient of which is lower than 100. The refractive index of the intermediate layer differs by less than 0.3 from the refractive index of at least one sub-layer of the first layer adjacent to the intermediate layer, and of at least one sub-layer of the second layer adjacent to the intermediate layer.

### CROSS REFERENCE TO RELATED APPLICATIONS

This application is a national phase entry under 35 U.S.C. § 371 of International Patent Application PCT/FR2022/051695, filed Sep. 8, 2022, designating the United States of America and published as International Patent Publication WO 2023/047037 A1 on Mar. 30, 2023, which claims the benefit under Article 8 of the Patent Cooperation Treaty to French Patent Application Serial No. FR2109949, filed Sep. 22, 2021.

### TECHNICAL FIELD

The field of the present disclosure is that of semiconductors and particularly of optoelectronics. It relates to a semiconductor structure comprising a first layer made of crystalline semiconductor joined to a second layer via an intermediate layer having a refractive index very close to those of the first and second layers.

### BACKGROUND

Vertical-cavity surface-emitting lasers (VCSELs) are increasingly being developed for the emergent mass-market applications that are facial recognition in the field of mobile telephony in particular, and light detection and ranging (lidar) for the automotive industry.

VCSELs 100 are produced on stacks of III-V semiconductor layers, via successive steps of epitaxial growth (FIGS. 1A and 1B). The composition, doping and thickness of each layer are precisely controlled to form, on the one hand, an active region 2 consisting of one or more quantum wells allowing the laser beam to be generated, and on the other hand, two Bragg mirrors 3a,3b that sandwich the active region 2 and that consist of an alternation of layers of high and low refractive indices.

It is known to form the stack of layers of a VCSEL 100 on a bulk substrate 1, as illustrated in FIG. 1A, for example, one made of gallium arsenide (GaAs) for laser wavelengths between 650 nm and 1300 nm, or one made of indium phosphide (InP) for laser wavelengths between 1300 nm and 2000 nm. To obtain a high-performance VCSEL 100, the bulk substrate 1 must have an excellent quality in order to play the role of epitaxial seed well and to guarantee the stack of layers is of high quality.

Alternatively, to address problems with cost related to the use of high-quality bulk substrates, a thin high-quality working layer 10 may be transferred to a carrier substrate 1′ the properties of which are more modest and/or tailored to other constraints, for example, integration or packaging of the VCSEL 100 (FIG. 1B). Transfer of such a working layer to a carrier substrate is especially proposed in document WO2021/125005.

Transfer of one or more thin layers may also be useful in the context of production of the VCSEL itself. For example, in the case where the Bragg mirrors 3a,3b require a very high number of alternations of layers because of limitations (due the epitaxial growth technique) on compositions and doping, it may be more favorable to transfer a set of thin layers (Bragg mirror) rather than to grow it by epitaxy. Reference may be made, for example, to the article by A. Syrbu et al., “1.5-mW single-mode operation of wafer-fused 1550-nm VCSELs,” IEEE Photonics Technology Letters, Volume: 16, Issue: 5, U.S. Plant Pat. No. 1,230-1232 May 2004.

Whenever transfer is employed, the joint between the thin working layer 10 and the carrier substrate 1′ must allow the high quality of the layer 10 to be preserved and prevent disruptions occurring in the operation of the VCSEL 100. A problem may result from the fact that direct bonding between a thin working layer 10 and a carrier substrate 1′, both made of III-V semiconductors, requires a plurality of steps to be carried out to prepare the surfaces to be joined, chemically, and that these steps may prove to be complex and therefore expensive.

### BRIEF SUMMARY

The present disclosure provides a solution that simplifies the fabrication of VCSELs, and more generally the fabrication of optoelectronic components, employing the transfer of a first layer to a second layer. It in particular relates to a semiconductor structure comprising a first layer made of crystalline semiconductor joined to a second layer also made of crystalline semiconductor, via an intermediate layer having a refractive index very close to that of at least one sub-layer of the first layer and of at least one sub-layer of the second layer, the sub-layers being adjacent to the intermediate layer. The intermediate layer further has a very low attenuation coefficient.

The present disclosure relates to a semiconductor structure for optoelectronic applications comprising:
a first layer made of a crystalline semiconductor, the layer being placed on
an intermediate layer including or adjacent to a direct-bonding interface, the intermediate layer being placed on
a second layer made of a crystalline semiconductor.

The semiconductor structure is noteworthy in that the intermediate layer is composed of a material that is different from those of the first and second layers and the refractive index of which differs by less than 0.3 from the refractive index:
of at least one sub-layer of the first layer adjacent to the intermediate layer, and
of at least one sub-layer of the second layer adjacent to the intermediate layer.

The intermediate layer further has an attenuation coefficient lower than 100.

According to some advantageous features of the present disclosure, which may be implemented alone or in any achievable combination:
the attenuation coefficient of the intermediate layer is lower than 10, or even lower than 1, or indeed even preferably as close as possible to 0;
the material of the intermediate layer is amorphous;
the material of the first layer is a single crystal of high crystal quality so as to form a seed for epitaxy;
the first layer forms all or some of a vertical-cavity surface-emitting laser (VCSEL);
the second layer is a carrier substrate having an optical transparency higher than 30%;
the semiconductor of the first layer is gallium arsenide, the semiconductor of the second layer is gallium arsenide, and the material of the intermediate layer is silicon;
the first layer is an active region of a vertical-cavity surface-emitting laser (VCSEL), and the second layer is a multilayer Bragg mirror of the laser;
the semiconductor of the first layer is indium phosphide, the semiconductor of at least one sub-layer of the second layer adjacent to the intermediate layer is gallium arsenide, and the material of the intermediate layer is zinc-germanium phosphide or boron carbide or zinc-silicon arsenide.

### BRIEF DESCRIPTION OF THE DRAWINGS

Other features and advantages of the present disclosure will become apparent from the following detailed description, with reference to the appended figures, in which:

FIGS. 1A and 1B show semiconductor structures for fabricating a VCSEL, according to the prior art;

FIG. 2 shows a semiconductor structure in accordance with the present disclosure;

FIG. 3 shows a semiconductor structure according to a first embodiment of the present disclosure;

FIGS. 4A-4G show steps of a process for fabricating a semiconductor structure according to a first embodiment of the present disclosure;

FIGS. 5A and 5B show steps of a process for fabricating a semiconductor structure according to a variant of the first embodiment of the present disclosure;

FIGS. 6A-6C show semiconductor structures according to a second embodiment of the present disclosure.

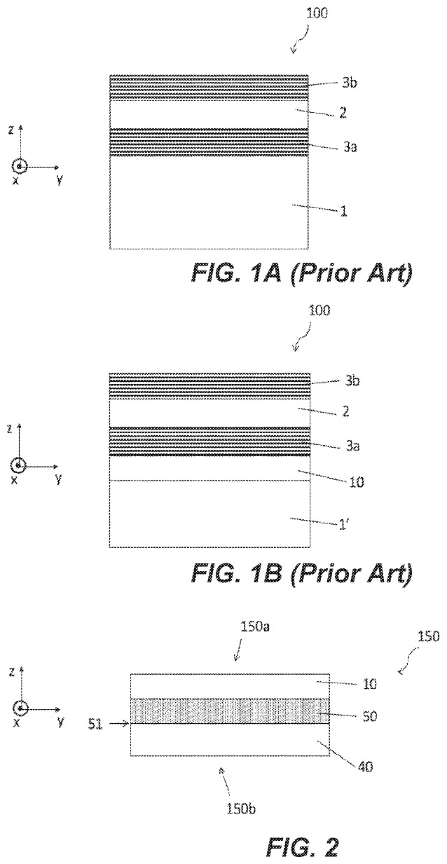

The figures are schematic representations that, for the sake of readability, have not been drawn to scale. In particular, the thicknesses of the layers along the z-axis are not to scale with respect to the lateral dimensions along the x-and y-axes.

In the figures, the same references will possibly have been used for elements of the same nature.

### DETAILED DESCRIPTION

Referring to FIG. 2, the present disclosure relates to a semiconductor structure 150 specially tailored to optoelectronic applications.

It comprises a first layer 10 made of a crystalline semiconductor, the layer being placed on an intermediate layer 50, itself placed on a second layer 40 made of a crystalline semiconductor. As illustrated in FIG. 2, these layers 10, 40, 50 lie parallel to a main plane (x, y) and have a thickness along a z-axis. By convention, the front side 150a of the semiconductor structure 150 is located on the side of the first layer 10 and its back side 150b is located on the side of the second layer 40.

The semiconductor structure 150 may take the form of a wafer, the diameter of which is, for example, between 50 mm and 200 mm. The semiconductor structure 150 is in this case intended to accommodate a plurality of optoelectronic components that will possibly be subsequently singulated. The semiconductor structure 150 may alternatively take the form of a die of smaller size, accommodating one optoelectronic component or a group of components.

The crystalline semiconductors forming the first layer 10 and the second layer 40, respectively, may be of the same nature or of different natures. Being intended for production of optoelectronic components, the first layer 10 and the second layer 40 are advantageously chosen from III-V semiconductor compounds such as gallium nitride, gallium arsenide, indium phosphide, and other binary, ternary or quaternary III-V compounds. It will be noted that the first layer 10 (and/or the second layer 40) will possibly be composed of a stack of sub-layers of different doping or compositions or have a uniform composition.

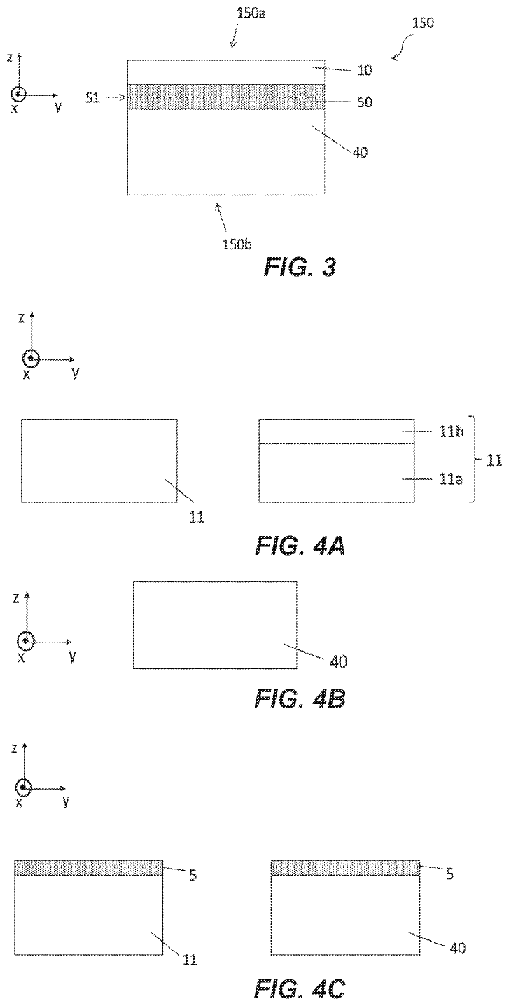

The semiconductor structure 150 according to the present disclosure further comprises a direct-bonding interface 51 (FIG. 3), the interface 51 being included in or adjacent to the intermediate layer 50. By direct bonding, what is meant is bonding that does not require an adhesive material and that is based on a molecular adhesion between the joined surfaces. There are a number of types of direct bonding, which especially differ in the temperature conditions, pressure conditions, atmosphere or the treatments carried out prior to bringing the surfaces into contact. Mention may be made of room-temperature direct bonding with or without prior plasma activation of the surfaces to be joined, atomic diffusion bonding (ADB), surface activated bonding (SAB), etc.

Since the semiconductor structure 150 is targeted at optoelectronic applications, all or some of the constituent layers of the semiconductor structure 150 are intended to be passed through by a light signal. Typically, the optoelectronic components produced on the structure 150 will possibly, depending on their type and their nature, transmit or receive the light signal, through the front side 150a or through the back side 150b of the semiconductor structure 150.

In order for the semiconductor structure 150 to be generic in character and able to accommodate a wide variety of types of optoelectronic component, the refractive index of the intermediate layer 50 differs by less than 0.3, or even by less than 0.2, from the refractive index:
of at least one sub-layer of the first layer 10, the sub-layer being adjacent to the intermediate layer 50, and
of at least one sub-layer of the second layer 40, the sub-layer being adjacent to the intermediate layer 50.

In other words, when the first layer 10 (the second layer 40, respectively) is formed from stacked sub-layers, the difference in refractive index between the sub-layer making contact with the intermediate layer 50 and the intermediate layer 50 is smaller than 0.3, or even smaller than 0.2. When the first layer 10 (the second layer 40, respectively) has a uniform composition, the difference in refractive index between the first layer 10 (the second layer 40, respectively) and the intermediate layer 50 is smaller than 0.3, or even smaller than 0.2.

In addition, the intermediate layer 50 has an attenuation coefficient k lower than 100, or even lower than 10, or indeed even lower than 1, and preferably also as close to zero as possible in order to limit the attenuation of the light signal intended to pass through the layer 50. This amounts to saying that the physico-chemical and mechanical properties of the intermediate layer 50 are chosen so as to guarantee a low attenuation coefficient.

It will be recalled that the refractive index of a material may be considered to be a complex number (n+ik) and to have a real part n (the aforementioned refractive index) and an imaginary part k (the attenuation coefficient).

The intermediate layer 50 of the structure 150 is further composed of a material different from those of the first and second layers 10, 40, especially because the intermediate layer 50 plays an additional role, namely that of promoting bonding of the first layer 10 and of the second layer 40.

By way of example, when the refractive index of the first layer 10 is equal to 3, the refractive index of the second layer 40 is between [3+0.3=3.30] and [3−0.3=2.70], as is the refractive index of the intermediate layer 50. The attenuation coefficient of the intermediate layer 50 is lower than 100, than 10, or than 1.

Thus, the intermediate layer 50 of the semiconductor structure 150 does not disrupt or hardly disrupts the light signal if the light signal must pass through the intermediate layer 50. In addition, the intermediate layer 50 promotes direct bonding between the first layer 10 and the second layer 40, thereby simplifying the surface-preparation steps carried out before they are joined, the material of the intermediate layer 50 especially being chosen for its ease of preparation; the material further permits an arrangement of atoms at low temperature, favorable to joint formation, while limiting stresses between the layers 10 and 40. It will also be noted that the lower the attenuation coefficient (i.e., the closer it gets to 0) the greater the flexibility in the choice of the thickness of the intermediate layer 50; in other words, with a very low attenuation coefficient, a thicker intermediate layer 50 may be employed: this may prove to be an advantageous way of increasing the quality of the direct bond.

In the semiconductor structure 150, the interface roughness between the various layers 10, 50, 40 or sub-layers is preferably lower than about 5 nm RMS (measured by atomic force microscopy (AFM) in scans of 10 microns×10 microns), in order to limit scattering of the light signal at the interfaces.

Advantageously, the material of the intermediate layer 50 is amorphous, so as to limit the stress field associated with bonding two materials, the crystal lattices of which are not aligned and/or the lattice parameters of which are different, and so as to avoid the formation of nano-bubbles at the bonding interface.

According to a first embodiment of the present disclosure, the semiconductor structure 150 is intended to accommodate VCSELs in a configuration such that the laser signal is emitted through the back side 150b of the semiconductor structure 150.

The material of the first layer 10 is a single crystal of high quality intended to form a seed for the epitaxial growth of the stack of layers comprising the active region 2 sandwiched between the two Bragg mirrors 3a,3b. The second layer 40 is a carrier substrate 40 having a high optical transparency (potentially better than that of the first layer 10), and typically higher than 30%. Advantageously, for essentially economic reasons, the carrier substrate 40 is of lower crystal quality than the first layer 10 (FIG. 3).

Typically, the semiconductor of the first layer 10 is gallium arsenide (GaAs), with a crystal quality allowing defect-free growth, and typically n-type GaAs (doped at ˜10¹⁸ at/cm³) tailored to the targeted application and having a dislocation density lower than 500/cm². The thickness of the first layer 10 is between 50 and 1500 nm.

The semiconductor of the second layer 40 is gallium arsenide and has a lower absorbance (better optical transparency) than the material of the first layer 10, at the operating length of the targeted component. The second layer 40, which forms the carrier substrate 40 of the semiconductor structure 150, does not require a high crystal quality in that it essentially plays the role of a mechanical carrier. The second layer 40 has a thickness, for example, between 200 and 2000 microns. With a view to passage of the light signal through the carrier substrate 40, which passage is required because the VCSEL emits through the back side 150b, the gallium arsenide of the carrier substrate 40 is further chosen to be semi-insulating, in order to limit the absorption of the light signal and therefore to enhance the efficiency of the VCSEL.

For a wavelength of the light signal of about 900 nm, the first layer 10 and the carrier substrate 40 have a refractive index equal to 3.52.

The material of the intermediate layer 50 is silicon (Si) and in particular an amorphous silicon. The thickness of the intermediate layer 50 may vary between 1 nm and 100 nm. For a wavelength of the light signal of about 900 nm, the intermediate layer 50 has a refractive index equal to 3.6 and an attenuation coefficient very close to 0.

A semiconductor structure 150 according to this first embodiment may be produced using a known prior-art process for transferring layers by bonding and thinning. Mention may especially be made of the Smart Cut™ process, which is particularly suitable for transferring very thin layers.

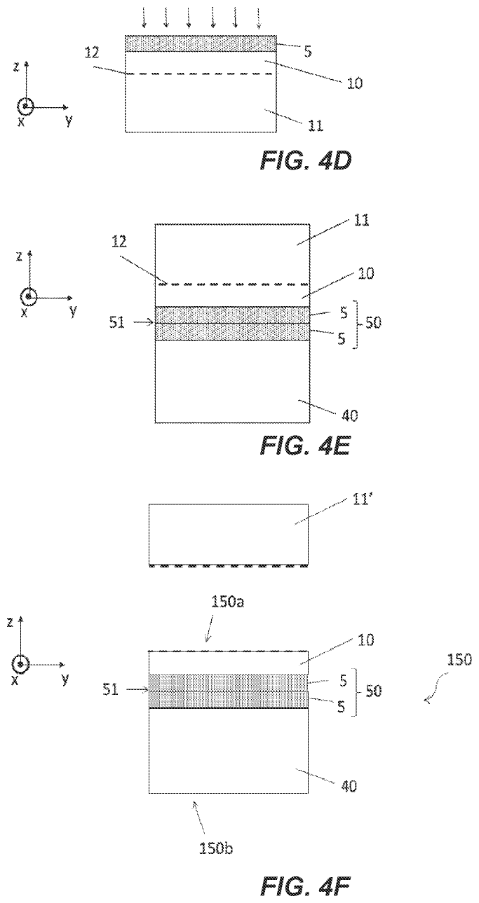

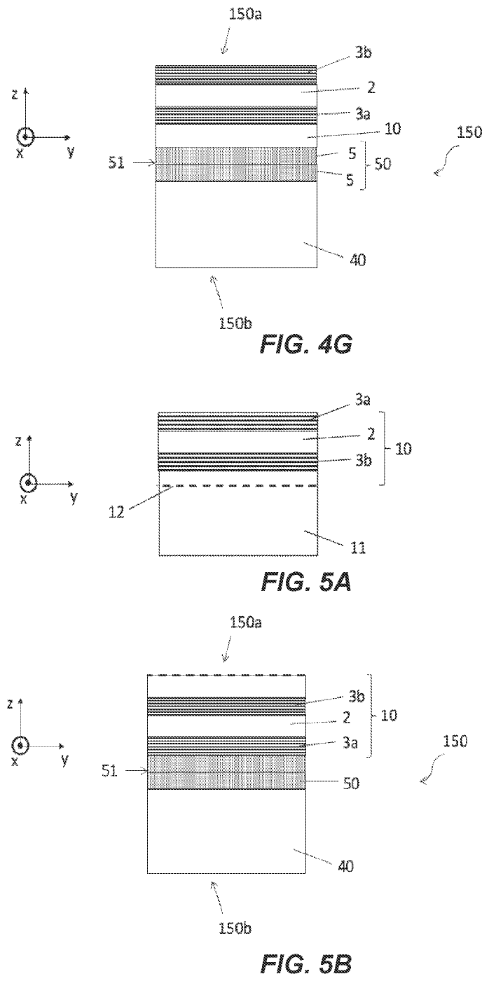

A first step a) involves providing a donor substrate 11, from which the first layer 10 will be taken (FIG. 4A). The donor substrate 11 may consist of a bulk GaAs substrate having the properties and characteristics expected for the first layer 10. Alternatively, it may comprise an initial substrate 11a and one or more high-quality surface layers 11b that are formed by, for example, epitaxy on the initial substrate 11a: the first layer 10 will then be taken from the one or more surface layers 11b.

A second step b) involves providing a carrier substrate 40 intended to form the second layer 40 of the semiconductor structure 150 (FIG. 4B). The quality and characteristics of the GaAs carrier substrate 40 are tailored to the targeted application, as mentioned above.

In a third step c), a bonding layer 5 made of amorphous Si is then deposited on the donor substrate 11 and/or on the carrier substrate 40 (FIG. 4C): after the two substrates 11, 40 have been joined, this (or these) bonding layer(s) 5 will be buried in the structure and will form the intermediate layer 50. The Si bonding layer 5 may be formed using a known technique employing chemical vapor deposition (CVD) (such as, for example, plasma-enhanced chemical vapor deposition (PECVD)), or epitaxy or even physical vapor deposition (PVD). Deposition is typically carried out at a temperature between 200° C. and 700° C. The typical thickness of a bonding layer 5 is between 1 nm and 20 nm.

A fourth step d) comprises introducing light ions into the donor substrate 11 so as to form a buried weak plane 12 that delineates, with a front side of the donor substrate 11, the layer that will be transferred, namely the first layer 10 (FIG. 4D). Typically, with a GaAs donor substrate, ion implantation of helium or hydrogen or of both these ions, in a dose of 1^{E}+16 at/cm² to 5^{E}+17 at/cm² and at an energy of about 100 keV, allows a buried weak plane 12 to be formed that, for implantation of helium ions (of hydrogen ions, respectively) will allow a first layer 10 of 500 nm (700 nm, respectively) thickness to be transferred. It will be noted that surface preparations and cleans will possibly be carried out before and/or after the implantation, so as to remove potential, organic or metal, particulate contamination.

A fifth step e) comprises joining the donor substrate 11 to the carrier substrate 40, so as to form an assembly bonded along a bonding interface 51 (FIG. 4E). This joining step involves bringing the two substrates 11, 40 into intimate contact via their front sides equipped with the one or more bonding layers 5. As mentioned above, room-temperature direct bonding or alternatively direct bonding under an atmosphere and at a controlled temperature (ADB or SAB) may be employed. Provision may of course be made for surface cleans or activations (for example, using a plasma) to be carried out before the sides to be joined are brought into contact. These surface preparations are easier than preparations involving a III-V material, because the cleaning and/or activation required before bonding of silicon require(s) conventional steps and equipment that are furthermore well understood in the semiconductor industry.

By way of example, ADB may be carried out under ultra-high vacuum after the bonding layer 5 made of amorphous silicon has been deposited on the substrates 11 and 40.

The bonded assembly may advantageously undergo a heat treatment in order to consolidate the bonding interface 51, typically at a temperature between 150° C. and 600° C., for a few minutes to a few hours.

FIG. 4E illustrates a bonding interface 51 located in the intermediate layer 50; the interface 51 may alternatively be located between the first layer 10 and the intermediate layer 50 when the bonding layer 5 is deposited only on the carrier substrate 40, or may be located between the carrier substrate 40 and the intermediate layer 50 when the bonding layer 5 is deposited only on the donor substrate 11. Even in the case where the bonding layer 5 is deposited only on one of the donor and carrier substrates 11, 40, direct bonding is facilitated.

A sixth step f) comprises separation along the buried weak plane 12, this occurring as a result of the presence and/or growth of cavities and micro-cracks in the plane (FIG. 4F). As is known per se, such a separation, for example, occurs during a heat treatment designed to cause cavities to develop and to be placed under pressure, and to lead to the spontaneous propagation of a splitting wave through the buried weak plane 12. The separating heat treatment typically corresponds to an anneal at 200° C. for 120 minutes. Alternatively or conjointly to the heat treatment, separation may be induced by a mechanical stress applied to the buried weak plane 12.

At the end of step f) the following are obtained: on the one hand, the semiconductor structure 150 with its first layer 10 placed on the intermediate layer 50, which itself is placed on the carrier substrate 40 (or second layer 40); and on the other hand, the remainder 11′ of the donor substrate.

Step f) may then comprise (cleaning, polishing, etching) surface treatments or other smoothing treatments, with a view to improving the surface quality of the first layer 10.

The structure 150 according to the present disclosure is advantageous with respect to a structure in which the first layer 10 and the second layer 40 are direct bonded without an intermediate layer, because it greatly facilitates the steps of preparing the surfaces before they are joined and ensures an excellent bond quality; it further removes the risk of formation of dislocations between the crystals of the first layer 10 and of the second layer 40. It will be recalled that bonding defects such as nano-bubbles and crystal defects (such as dislocations) are likely to disrupt a light signal passing through the bonding interface 51, this potentially being detrimental to certain optoelectronic components liable to be produced on the semiconductor structure 150.

Successive epitaxial growth steps g), which are intended to produce the one or more optoelectronic components, in the present case one or more VCSELs, may then be applied to the semiconductor structure 150, the first layer 10 being used as an epitaxial seed (FIG. 4G). These steps, which are known in the prior art, in particular lead to formation of the active region 2 of the VCSEL, which region is sandwiched between two Bragg mirrors 3a,3b, which are based on gallium arsenide.

According to one variant of the first embodiment of the semiconductor structure 150, the first layer 10 forms all or some of a VCSEL, the second layer 40 again being the carrier substrate 40 of high optical transparency at the nominal operating wavelength of the optical component and optionally of low crystal quality. In this variant, the first layer 10 therefore comprises a plurality of sub-layers.

In step a), the donor substrate 11, for example, comprises the active region 2 and the two Bragg mirrors as illustrated in FIG. 5A, or some of this stack. All or some of the VCSEL is thus transferred by way of first layer 10 at the end of step f) (FIG. 5B).

In the first embodiment and its variant, the fact that the intermediate layer 50 has a very low attenuation coefficient (close to 0) and a refractive index close to that of the first layer 10 (or that of a sub-layer of the first layer 10, adjacent to the intermediate layer 50) and to that of the carrier substrate 40, permits the laser signal of the VCSEL to be emitted through the back side 150b of the semiconductor structure 150, without disruption and attenuation of the signal as a result of passage through the intermediate layer 50 and carrier substrate 40.

Of course, the semiconductor structure 150 according to this first embodiment is also suitable for other types of optoelectronic component that transmit or receive an optical signal, irrespective of whether the optical signal is transmitted or received through the front side 150a or through the back side 150b.

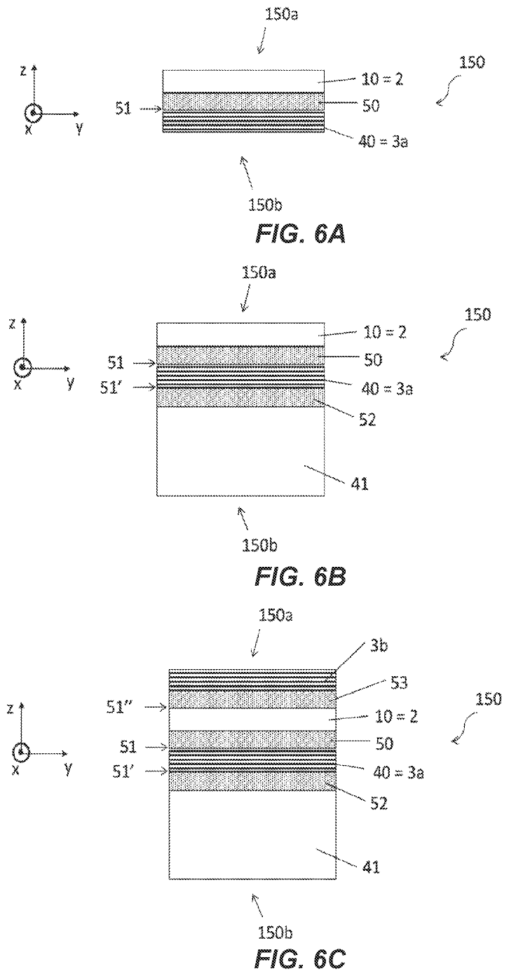

According to a second embodiment of the present disclosure, the semiconductor structure 150 is again intended to accommodate a VCSEL. However, in this embodiment, the first layer 10 forms an active region 2 of the VCSEL, and the second layer 40 forms a multilayer Bragg mirror 3a (FIG. 6A).

Typically, the semiconductor of the first layer 10 comprises at least one layer of indium phosphide (InP) having a dislocation density lower than 5000/cm². The thickness of the first layer 10 is between 10 and 1500 nm. For a wavelength of the light signal of about 1.55 microns, the first layer 10 has a refractive index equal to 3.1.

The second layer 40 comprises gallium arsenide and is formed from a plurality of stacked sub-layers that are doped and have compositions (the reader is especially referred to the article by A. Syrbu cited in the introduction) such as to form a Bragg mirror for a light signal of wavelength of 1.55 microns. The sub-layers are formed from, for example, GaAs (refractive index of about 3.37 at the wavelength in question), from aluminum arsenide (AlAs) (refractive index of about 2.89) and from ternary AlGaAs compounds. The thickness of the second layer 40 is between 1 and 6 μm.

The material of the intermediate layer 50 is zinc-germanium phosphide (ZnGeP₂) or boron carbide (B₄C) or zinc-silicon arsenide (ZnSiAs₂). For a wavelength of the light signal of about 1.55 microns, an intermediate layer 50 made of ZnGeP₂, of B₄C or of ZnSiAs₂ has a refractive index equal to 3.17, 3.25 or 3.26, respectively, and an attenuation coefficient lower than 10.

The thickness of the intermediate layer 50 may vary between 1 nm and 100 nm.

A sub-layer of the second layer 40 that has the refractive index closest to that of the first layer 10 (i.e. one with a difference in refractive index smaller than 0.3) is positioned closest to the first layer 10, i.e. adjacent to the intermediate layer 50.

In the second embodiment, the semiconductor structure 150 advantageously comprises a carrier substrate 41 placed under the second layer 40 (FIG. 6B). The carrier substrate 41 does not require a high crystal quality in that it essentially plays the role of a mechanical carrier. The carrier substrate 41 may be formed from InP or from GaAs. The carrier substrate 41 has a thickness, for example, between 250 and 1000 microns depending on its diameter. In the case where the carrier substrate 41 must be passed through by the light signal, for example, in the case where the VCSEL must emit through the back side 150b, the carrier substrate 41 is chosen to have the lowest possible attenuation coefficient k and ideally one equal to 0, in order to limit the absorption of the light signal and therefore promote the efficiency of the VCSEL.

A second intermediate layer 52, of the same nature as the intermediate layer 50, may be inserted between the carrier substrate 41 and the second layer 40; this option is especially advantageous in the case where the light signal must pass through the carrier substrate 41, as it limits disruption and attenuation of the signal. A second bonding interface 51′ is located in the second intermediate layer 52, or is adjacent to the second intermediate layer 52.

A semiconductor structure 150 according to this second embodiment may be produced using a known prior-art process for transferring layers by bonding and thinning, in particular the Smart Cut™ process detailed with reference to the first embodiment.

Similar steps to those mentioned above are implemented, and potentially repeated in the case of a second bonding interface 51′.

In this second embodiment, the successive epitaxial growth steps g) intended to produce the one or more VCSELs involves forming the second Bragg mirror 3b on the first layer 10 (which comprises the active region 2 of the VCSEL). Alternatively, the epitaxial growth steps are replaced by the transfer of a layer forming the second Bragg mirror 3b, via a third intermediate layer 53, of the same nature as the intermediate layer 50 (FIG. 6C). A third bonding interface 51″ is located in the third intermediate layer 53, or is adjacent to the third intermediate layer 53.

The semiconductor structure 150 according to the second embodiment allows a VCSEL emitting at a wavelength of about 1.55 μm to be fabricated while simplifying the fabrication of the Bragg mirrors 3a,3b, which commonly require a very high number of successive epitaxial InP layers. Transfer of a GaAs Bragg mirror (requiring a smaller stack of layers) to an InP active region, via an intermediate layer 50 having a low attenuation coefficient and a difference in refractive index smaller than 0.3 with the index of the active region 2 (first layer 10) allows an efficient VCSEL to be produced.

More generally, the semiconductor structure 150 according to this second embodiment is compatible with a VCSEL emitting through the front side 150a or through the back side 150b, because of the use of a second intermediate layer 52, or even of a third intermediate layer 53, having a difference in refractive index smaller than 0.3 with that of the first layer 10 (or active region 2), and having a low attenuation coefficient.

Of course, the present disclosure is not limited to the embodiments described and variants of embodiment may be implemented without departing from the scope of the invention as defined by the claims.

In particular, the semiconductor structure 150 according to the present disclosure may be tailored to other optoelectronic applications such as photodetectors, for example.

1. A semiconductor structure for optoelectronic applications comprising:
a first layer made of a crystalline semiconductor, the first layer being disposed on
an intermediate layer including or adjacent to a direct-bonding interface, the intermediate layer being disposed on
a second layer made of a crystalline semiconductor,
wherein the intermediate layer is composed of a material different from those of the first and second layers, and the intermediate layer has an attenuation coefficient lower than 100, and a refractive index that differs by less than 0.3 from the refractive index:
of at least one sub-layer of the first layer adjacent to the intermediate layer, and
of at least one sub-layer of the second layer adjacent to the intermediate layer, and
wherein the crystalline semiconductor of the first layer comprises gallium arsenide, the crystalline semiconductor of the second layer comprises gallium arsenide, and the material of the intermediate layer comprises silicon.

2. The semiconductor structure of claim 1, wherein the material of the intermediate layer is amorphous.

3. The semiconductor structure of claim 2, wherein the crystalline material of the first layer comprises a single crystal of sufficiently high crystal quality to form a seed for epitaxy.

4. The semiconductor structure of claim 1, wherein the first layer forms all or some of a vertical-cavity surface-emitting laser.

5. The semiconductor structure of claim 4, wherein the second layer is a carrier substrate having an optical transparency higher than 30%.

6. The semiconductor structure of claim 1, wherein the attenuation coefficient of the intermediate layer is lower than 1.

7. The semiconductor structure of claim 1, wherein the crystalline material of the first layer comprises a single crystal of sufficiently high crystal quality to form a seed for epitaxy.

8. The semiconductor structure of claim 2, wherein the first layer forms all or some of a vertical-cavity surface-emitting laser.

9. The semiconductor structure of claim 3, wherein the second layer is a carrier substrate having an optical transparency higher than 30%.

10. A semiconductor structure for optoelectronic applications comprising:
a first layer comprising crystalline gallium arsenide;
a second layer comprising crystalline gallium arsenide; and
an intermediate layer comprising silicon disposed directly between and in direct physical contact with each of the first layer and the second layer, the intermediate layer having an attenuation coefficient lower than 100, the intermediate layer having a refractive index that differs by less than 0.3 from a refractive index:
of at least a portion of the first layer directly adjacent to and in direct physical contact with the intermediate layer, and
of at least a portion of the second layer directly adjacent to and in direct physical contact with the intermediate layer; and
wherein a direct bonding interface is disposed within the intermediate layer, at an interface between the intermediate layer and the first layer, or at an interface between the intermediate layer and the second layer.

11. The semiconductor structure of claim 10, wherein the material of the intermediate layer is amorphous.

12. The semiconductor structure of claim 11, wherein the crystalline material of the first layer comprises a single crystal of sufficiently high crystal quality to form a seed for epitaxy.

13. The semiconductor structure of claim 10, wherein the first layer forms all or some of a vertical-cavity surface-emitting laser.

14. The semiconductor structure of claim 13, wherein the second layer is a carrier substrate having an optical transparency higher than 30%.

15. The semiconductor structure of claim 10, wherein the attenuation coefficient of the intermediate layer is lower than 1.

16. The semiconductor structure of claim 10, wherein the crystalline material of the first layer comprises a single crystal of sufficiently high crystal quality to form a seed for epitaxy.

17. The semiconductor structure of claim 11, wherein the first layer forms all or some of a vertical-cavity surface-emitting laser.

18. The semiconductor structure of claim 12, wherein the second layer is a carrier substrate having an optical transparency higher than 30%.
